(19) United States
(12) Patent Application Publication
(10) Pub. No.: US 2018/0282902 A1
(43) Pub. Date: Oct. 4, 2018

(54) SIC SINGLE CRYSTAL INGOT

(71) Applicant: SHOWA DENKO K. K., Tokyo (JP)

(72) Inventor: Masashi NAKABAYASHI, Tokyo (JP)

(73) Assignee: SHOWA DENKO K. K., Tokyo (JP)

(21) Appl. No.: 15/765,070

(22) PCT Filed: Sep. 30, 2016
(86) PCT No.: PCT/JP2016/079148

§ 371 Date: Mar. 30, 2018

(30) Foreign Application Priority Data
Oct. 2, 2015 (JP) 2015-196622
Mar. 3, 2016 (JP) 2016-041626

(51) Int. Cl. C30B 29/36; C30B 23/00

(52) U.S. Cl. CPC C30B 29/36; C30B 23/002

(57) ABSTRACT

An SiC single crystal ingot including a silicon carbide (SiC) single crystal formed on a seed crystal, a crystal growth end of a front end of the ingot having a convex shape. An SiC single crystal substrate cut out from a part of a relative height in a height direction of the ingot of at least 0.2 to 0.8 in range has a basal plane dislocation density and threading screw dislocation density observed at the surface of the substrate that are respectively predetermined values or less. Further, the Raman index of the difference (A/B) of the Raman Shift value (A) measured at the center part of the substrate and the Raman Shift value (B) measured at the peripheral parts is a predetermined value or less.

### FIELD

This invention relates to a silicon carbide single crystal ingot comprising a seed crystal on which a silicon carbide single crystal is formed, more particularly relates to a silicon carbide single crystal ingot with low dislocation densities of basal plane dislocations and threading screw dislocations, excellent crystal quality, and small elastic strain.

### BACKGROUND

Silicon carbide (SiC) is a wide bandgap semiconductor having a broad bandgap of 2.2 to 3.3 eV. SiC has excellent physical and chemical characteristics, so for example there is much R&D underway on using SiC to fabricate semiconductor devices, high frequency electronic devices, high withstand pressure, high output electronic devices, blue to ultraviolet short wavelength optical devices, and other SiC devices.

To promote the practical application of SiC devices, production of large-size SiC single crystals is essential. At the present time, most large-size SiC single crystals are being obtained from bulk SiC single crystals grown by the sublimation recrystallization method using seed crystals (also called the “modified Lely method”). In the sublimation recrystallization method, sublimation materials of SiC are held inside a crucible body for crystal growth, a seed crystal consisting of an SiC single crystal is attached to the lid of the crucible, and the crucible covered by an insulating material is placed inside of a double quartz tube. Further, the atmosphere is controlled while using an induction heating coil to raise the sublimation material side to a high temperature, the seed crystal side is made a low temperature to form a temperature gradient in the growth direction, and the material is made to sublimate so as to make a recrystallized SiC single crystal grow on the seed crystal. Further, after obtaining a substantially columnar SiC bulk single crystal (SiC single crystal ingot), in general this is cut into thicknesses of 300 to 600 μm or so to produce SiC single crystal substrates. Further, epitaxial SiC single crystal wafers obtained by growing SiC epitaxial films on these SiC single crystal substrates by the methods such as the thermal CVD method are used for fabrication of SiC devices.

At the present time, diameter 51 mm (2 inch) to 100 mm SiC single crystal substrates (below, sometimes simply referred to as “single crystal substrates” or “substrates”) are obtained from SiC single crystal ingots produced by the modified Lely method (below, sometimes simply referred to as “ingots”). Examples of successful development of 150 mm wafers are reported (see for example NPL 1). In this way, in the process of the full-fledged practical use of devices using 100 mm to 150 mm substrates (4 inch to 6 inch substrates), the quality of the SiC single crystal substrates, as represented by indicators such as the dislocation density, is viewed more importantly than ever before since it has a large effect on the performance and yield of devices at the time of mass production.

In this modified Lely method, an SiC single crystal is grown after the inside of the crucible reaches a temperature over 2000° C., so it is believed that unavoidably internal stress is generated in the obtained ingot and that this remains as elastic strain or dislocations (plastic strain) inside the final single crystal substrates. Here, there are reports that the currently commercially available SiC single crystal substrates have 2×10³ to 2×10⁴ (/cm²) basal plane dislocations (BPD), 8×10² to 10³ (/cm²) threading screw dislocations (TSD), and 5×10³ to 2×10⁴(/cm²) threading edge dislocations (TED) (see NPL 2). Among these, for example, BPDs cause defects in the oxide films of devices and cause insulation breakdown. Further, TSDs are known to be the cause of leakage current in devices. To fabricate high performance SiC devices, SiC single crystals with small densities of these BPDs and TSDs has been sought.

Therefore, as art for reducing the dislocation densities, for example, there is the method which comprises the steps of growing an initial growth layer of an SiC single crystal at a predetermined growth pressure and substrate temperature and gradually reducing the substrate temperature and pressure while further growing the crystal to thereby obtain an SiC single crystal with few micropipes and TSDs (see PTL 1). Further, there is the method of growing an initial growth layer of an SiC single crystal by a predetermined growth pressure and substrate temperature then maintaining the substrate temperature as is while reducing the pressure to raise the speed of growth to further grow the crystal and thereby keep down the formation of micropipes and reduce the dislocation densities of TSDs etc. (see PTL 2). Further, there is the method which comprises the steps of matching the concentrations of added elements in the region of the crystal grown near the seed crystal with the concentrations of added elements in the seed crystal to thereby reduce the densities of micropipe defects and dislocation defects (see PTL 8). Further, there is the method which comprises reducing defects by limiting the frequency of vibration given to the processing vessel in which the seed crystal substrate and material powder are set when growing the silicon carbide (see PTL 9). However, in each case, the effect of reduction of TSDs was not sufficient. Further reduction is required for fabrication of high performance SiC devices. Further, the reduction of BPDs is not touched upon at all in these methods.

Further, if the elastic strain of the substrate is large and deviation occurs in the crystal orientations in the plane of the substrate, problems such as step flow abnormalities are caused in the epitaxial growth process when obtaining an epitaxial SiC single crystal wafer, and the large elastic strain ends up affecting the device characteristics. The large elastic strain also causes warping of the SiC single crystal substrate. Such warping of the substrate gives rise to problems such as defocusing in the lithographic process or leakage of material gas to the back surface in the middle of the epitaxial growth process. Further, this can cause handling problems in wafer transport etc. or damage at the time of pickup by chucks.

Therefore, as one of the arts for growth easing the internal stress of a single crystal ingot, there is disclosed the method of using a single crystal production apparatus provided with a temperature gradient control member arranged around a seed crystal or an SiC single crystal grown on the same and a local temperature gradient easing member set between the seed crystal or SiC single crystal and the temperature gradient control member (see PTL 3). However, the object of the art relating to this single crystal production apparatus is to reduce the local maximum value of the temperature gradient formed in the single crystal grown right above the seed crystal and suppress the formation and propagation of cracks inside the grown crystal. The growth conditions of the portion processed into substrates in the grown ingot are fundamentally unchanged from the prior methods up to then.

Further, the methods of easing internal stress of an SiC single crystal ingot or SiC single crystal substrate by annealing the ingot or substrate at a 2000° C. or so high temperature have been known (for example, see PTLs 4 and 5). However, according to these methods, while it may be considered there is an effect of reducing the elastic strain, applying a high temperature heat load to an SiC single crystal from the outside to cause rearrangement of atoms includes temperature raising and cooling processes and forms a new temperature distribution. For this reason, due to the temperature imbalance, a strong stress field is created inside the crystal and new dislocations end up being formed. Incidentally, the increase in dislocation densities of crystals after annealing in the examples of PTL 5 can be said to show this phenomenon.

On the other hand, the inventors succeeded in obtaining an SiC single crystal substrate with low dislocation densities and small elastic strain (see PTL 6). It had been known in the past to quantitatively measure the magnitude of stress by Raman spectroscopy (see PTL 7), but no method of evaluation of the elastic strain affecting the device yield had then been clarified. PTL 6 clarified a method of evaluation of the elastic strain affecting the device yield. The SiC single crystal wafer disclosed in PTL 6 particularly is a diameter 100 mm or more (4 inch or more) SiC single crystal substrate in which a BPD density observed on its surface is 500/cm² or less and a TSD density is 300/cm² or less and in which the Raman index represented by a difference (A-B) of a Raman Shift value (A) measured at a center part of the substrate and a Raman Shift value (B) measured at an edge part is 0.15 or less. In the production of such an SiC single crystal substrate, it is considered that elastic strain and dislocations (plastic strain) can be decreased by suppressing changes in temperature of the ingot in the crystal growth process and reducing the formation of internal stress.

### CITATION LIST

### Patent Literature

PTL 1. Japanese Patent Publication No. 2002-284599A
PTL 2. Japanese Patent Publication No. 2007-119273A
PTL 3. Japanese Patent Publication No. 2013-139347A
PTL 4. Japanese Patent Publication No. 2006-290705A
PTL 5. Japanese Patent Publication No. 2005-93519A
PTL 6. Japanese Patent Publication No. 2015-59072A
PTL 7. Japanese Patent Publication No. 2015-514673A
PTL 8. WO2010/044484A
PTL 9. Japanese Patent Publication No. 2013-67523A

### Nonpatent Literature

NPL 1. A. A. Burk et al., Mater. Sci. Forum, 717-720, (2012) pp. 75-80
NPL 2. Noboru Otani, Preprints of 17th Meeting on SiC and Related Wide Bandgap Semiconductors, 2008, p. 8

### SUMMARY

### Technical Problem

As explained above, in improving the yield and performance of SiC devices, reduction of the BPD density and TSD density of the SiC single crystal substrate is particularly important, but it is not sufficient to just lower these dislocation densities. That is, if the elastic strain of the SiC single crystal substrate is large, a good epitaxial thin film cannot be formed. Further, warping of the substrate is incurred so various problems end up being caused.

The SiC single crystal substrate described in PTL 6 can be said to be art extremely useful in the point of enabling these problems to be solved. In this regard, the SiC single crystal ingot disclosed in PTL 6 has a small bulk region from which substrates enabling the formation of a good quality epitaxial thin film can be taken, so the number of such SiC single crystal substrates with low dislocation densities and small elastic strain which can be taken out from a single SiC single crystal ingot is limited. On this point, there is still room for improvement in the SiC single crystal ingot disclosed in this PTL 6.

Therefore, the inventors advantaged further research and development and as a result discovered that by controlling the change of temperature of the ingot in the process of crystal growth by the modified Lely method (sublimation recrystallization method using seed crystal) and optimizing the temperature gradient of the ingot in the crystal growth direction, it is possible to obtain an ingot having a low BPD density and TSD density and a small elastic strain substantially as a whole.

Therefore, an object of the present invention is to provide an SiC single crystal ingot having low dislocation densities of basal plane dislocations and threading screw dislocations, excellent crystal quality, and further small elastic strain and having a practical height.

### Solution to Problem

That is, the gist of the present invention is as follows:

(1) An SiC single crystal ingot comprising a silicon carbide (SiC) single crystal formed on a seed crystal,
a crystal growth end of a front end of the ingot having a convex shape,
wherein, when a bottom surface of the ingot at the seed crystal side is zero and a height of the crystal growth end at a position inside from a side surface of the ingot by 10% of the diameter of the ingot is 1, an SiC single crystal substrate cut out from a part of a relative height in a height direction of the ingot of at least 0.2 to 0.8 in range has a basal plane dislocation density of 1000/cm² or less and a threading screw dislocation density of 500/cm² or less at the surface of the substrate, and a Raman index of a difference (A/B) of a Raman Shift value (A) measured at a center part of the substrate and a Raman Shift value (B) measured at an edge part is 0.20 or less.
(2) The SiC single crystal ingot according to (1),
wherein, when a bottom surface of the ingot at the seed crystal side is zero and a height of the crystal growth end at a position inside from a side surface of the ingot by 10% of the diameter of the ingot is 1, an SiC single crystal substrate cut out from a part of a relative height in a height direction of the ingot of at least 0.2 to 0.9 in range has a basal plane dislocation density of 1000/cm² or less at the surface of the substrate and a threading screw dislocation density of 500/cm² or less, and a Raman index of the difference (A/B) of the Raman Shift value (A) measured at the center part of the substrate and the Raman Shift value (B) measured at the edge part is 0.20 or less.
(3) The SiC single crystal ingot according to (1),
wherein, when a bottom surface of the ingot at the seed crystal side is zero and a height of the crystal growth end at a position inside from a side surface of the ingot by 10% of the diameter of the ingot is 1, an SiC single crystal substrate from a part of a relative height in a height direction of the ingot of at least 0.2 to 0.8 in range has a basal plane dislocation density of 500/cm² or less at the surface of the substrate and a threading screw dislocation density of 300/cm² or less, and a Raman index of the difference (A/B) of the Raman Shift value (A) measured at the center part of the substrate and the Raman Shift value (B) measured at the edge part is 0.15 or less.
(4) The SiC single crystal ingot according to any one of (1) to (3), wherein, when a bottom surface of the ingot at the seed crystal side is zero and a height of the crystal growth end at a position inside from a side surface of the ingot by 10% of the diameter of the ingot is 1, an SiC single crystal substrate from a part of a relative height in a height direction of the ingot of at least 0.2 to 0.9 in range has a basal plane dislocation density of 500/cm² or less and a threading screw dislocation density of 300/cm² or less at the surface of the substrate, and a Raman index of the difference (A/B) of the Raman Shift value (A) measured at the center part of the substrate and the Raman Shift value (B) measured at an edge part is 0.15 or less.
(5) The SiC single crystal ingot according to any one of (1) to (4), which has a size giving a diameter 4 inch to less than 6 inch SiC single crystal substrate.
(6) The SiC single crystal ingot according to any one of (1) to (4), which has a size giving a diameter 6 inch or more SiC single crystal substrate.
(7) The SiC single crystal ingot according to any one of (1) to (6), wherein a total of a basal plane dislocation density and threading screw dislocation density observed at the surface of the substrate is 1000/cm or less.
(8) The SiC single crystal ingot according to any one of (1) to (7), which has substantially a single polytype.
(9) The SiC single crystal ingot according to any one of (1) to (8), wherein a difference in height (O-E) between a center point O of a crystal growth end corresponding to a position of the ingot height and an edge point E on the crystal growth end corresponding to a position inside from a side surface of the ingot by 10% of the diameter is 1 mm to 7 mm
(10) The SiC single crystal ingot according to any one of (1) to (9) wherein an ingot height is 25 mm or more.

The silicon carbide (SiC) single crystal ingot of the present invention is low in dislocation densities of basal plane dislocations and threading screw dislocations and excellent in crystal quality substantially as a whole and further is small in elastic strain and is provided with a practical height. For this reason, according to the SiC single crystal ingot of the present invention, the dislocation densities of basal plane dislocations and threading screw dislocations of the ingot substantially as a whole are low and, further, a large number of SiC single crystal substrates with small elastic strain can be cut out. Further, according to such an SiC single crystal substrate, it is possible to improve the yield and performance of SiC devices. In particular, the present invention achieves an SiC single crystal substrate having such characteristics in a large substrate with a diameter of 100 mm or more, so it is possible to keep down the cost of SiC devices. This can be said to contribute to the increased spread of SiC devices.

### BRIEF DESCRIPTION OF DRAWINGS

FIG. 1 is a schematic explanatory view of a crystal growth apparatus used for growing an SiC single crystal by the modified Lely method.

FIG. 2 is a schematic explanatory view showing a crystal growth apparatus for suppressing a change in a temperature distribution of an ingot during crystal growth.

FIG. 3 is a schematic explanatory view showing one example of a crystal growth apparatus for suppressing a change in a temperature distribution of an ingot during crystal growth.

FIG. 4 is a schematic explanatory view showing one example of a crystal growth apparatus for suppressing a change in a temperature distribution of an ingot during crystal growth.

FIGS. 5A and 5B are explanatory views schematically showing a temperature gradient Δt₂ in a crystal growth direction of an ingot, wherein FIG. 5A shows the case of a conventional example and FIG. 5B shows the case of the present invention.

FIG. 6 is a schematic view for explaining a shape of an ingot.

FIG. 7 is an explanatory view showing positions of measurement of etch pits at a surface of an SiC single crystal substrate.

### DESCRIPTION OF EMBODIMENTS

Below, the present invention will be explained in detail. The SiC single crystal ingot in the present invention comprises an SiC single crystal having a crystal growth end of a front end of the ingot having a convex shape, has a low basal plane dislocation (BPD) density and threading screw dislocation (TSD) density in the part having a relative height with respect to the height of the ingot in this height direction (below, this height will be simply referred to as the “relative height”, while a position having this “relative height” will be simply referred to as a “relative height position”) of at least 0.2 to 0.8 in range, preferably 0.2 to 0.9 in range in range, and has a small elastic strain when a bottom surface of the ingot at the seed crystal side is zero and a height of a crystal growth end at a position inside from a side surface of the ingot by 10% of the diameter of the ingot is 1. Note that, the point where the above-mentioned relative height is 1 (below, also referred to as the “edge point”) generally is also called the “effective height (H′)” of the ingot considering the processing margin at the front end of the ingot in the crystal growth direction.

In this, regarding the BPD density, in the case of an SiC single crystal ingot enabling an SiC single crystal substrate with a diameter of 4 inches to less than 6 inches to be obtained (below, called “less than 6 inch substrate-use ingot”), each of the SiC single crystal substrates cut out from the part with a relative height position in the height direction of at least 0.2 to 0.8 in range in the direction of the horizontal cross-section of the ingot (that is, direction parallel to surface of seed crystal) had a BPD density of 500/cm² or less, preferably 300/cm² or less, more preferably 100/cm² or less. Further, in the case of an SiC single crystal ingot enabling an SiC single crystal substrate with a diameter of 6 inches or more to be obtained (below, called “6 inch or more substrate-use ingot”), each of the SiC single crystal substrates cut out from the part with the above relative height position had a BPD density of 1000/cm² or less, preferably 500/cm² or less, more preferably 300/cm² or less.

Further, regarding the TSD density, in the case of a less than 6 inch substrate-use ingot, each of the SiC single crystal substrates cut out from the above range of relative height position had a TSD density of 300/cm² or less, preferably 200/cm² or less, more preferably 100/cm² or less. Further, in the case of a 6 inch or more substrate-use ingot, each of the SiC single crystal substrates cut out from the part with the above range of relative height position had a TSD density of 500/cm² or less, preferably 300/cm² or less, more preferably 200/cm² or less.

Here, in both BPD and TSD, it is believed that if the densities fall to levels lower than 100/cm², there is substantially almost no adverse effect on a device. In each of the substrate-use ingots according to the present invention, it is possible to obtain limited substrates with such extremely low dislocation densities from specific parts thereof. According to the present invention, the minimum values of the BPD density and TSD density able to be satisfied in the range of relative height position in the height direction of an ingot such as explained above, at the present point of time, are a BPD density of 20/cm² and a TSD density of 60/cm² in the case of a less than 6 inch substrate-use ingot. Further, according to the present invention, in a 6 inch or more substrate-use ingot, the minimum value of the BPD density is 70/cm², and the minimum value of the TSD density is 90/cm². These values are the substantive lower limit values of the dislocation densities.

Further, as explained above, both BPDs and TSDs become obstacles to actual use of devices. For this reason, in the case of either of the substrate-use ingots, the total density of BPDs and TSDs should be 1000/cm² or less. In this case, remarkable improvements in the device performance and yield can be expected. Preferably, the total density of the BPDs and TSDs should be 500/cm² or less, more preferably 300/cm² or less.

On the other hand, the elastic strain is measured using the method described in PTL 6. That is, when cutting out any SiC single crystal substrate from inside the above-mentioned range of relative height position, the elastic strain is evaluated by the Raman index showing the difference (A/B) of the Raman Shift value (A) measured at the center part of the substrate and the Raman Shift value (B) measured at the edge part of the substrate. In general, as the method of evaluation of elastic strain, there are several methods in addition to precision measurement of a lattice constant by X-rays, but with these methods of measurement, the elastic strain is expressed by a vector, so advanced analytical techniques are required for evaluating the degree of effect on a device. Further, the measurement itself ends up requiring time and skill. As opposed to this, the above Raman index is expressed as a difference of reciprocals of the Raman scattered light peaks of SiC between the center part and an edge part of the substrate. It can be expressed by conversion of the vector quantity of the elastic strain to a scalar quantity. The measurement time is short and, further, evaluation is possible without regard as to the size of the substrate. Note that, regarding the center part and edge part of the substrate, as shown in the later explained examples, typically the former can be made the center (center point) of the substrate, while the latter can be made a position 2 mm away from the edge of the substrate toward the center direction.

Here, when the sign of the Raman index is positive, the larger the value of the Raman index, the larger the elastic strain of the SiC single crystal substrate. The elastic strain of the substrate becomes a cause of disturbance in the step direction and height of the substrate surface and ends up causing a drop in the quality of the epitaxial thin film formed at the surface. In the present invention, the Raman index of each of the SiC single crystal substrates cut out from the above range of relative height position is, in the case of a less than 6 inch substrate-use ingot, 0.15 or less, preferably 0.10 or less. Further, in the case of a 6 inch or more substrate-use ingot, the Raman index in each case is 0.20 or less, preferably 0.15 or less. Note that, the Raman index in an SiC single crystal substrate is usually a positive value, but sometimes it may become negative when produced under special manufacturing conditions. Obtaining a large absolute value at the minus side is generally considered difficult, but even if becoming smaller than −0.20, again, there is an effect on device fabrication, so in all substrate-use ingots, the lower limit value of the Raman index may be made −0.20.

In the present invention, as explained above, in a less than 6 inch substrate-use ingot and 6 inch or more substrate-use ingot, the dislocation densities and elastic strains of the cut out SiC single crystal substrates are defined under different conditions. The reason is that, for example, a diameter 6 inch or more (150 mm or more) SiC single crystal substrate is often used for fabricating mass production, inexpensive types of devices. On the other hand, a diameter less than 6 inch, that is, 4 to 5 inch (100 to 125 mm) SiC single crystal substrate is sometimes used for fabricating high performance devices and is required to have higher quality.

Here, the specific size of a less than 6 inch substrate-use ingot changes depending on the degree of processing of the outer circumference, processing of the end face, and other shaping. However, in general, in the state after crystal growth by the modified Lely method and before shaping (as-grown), an ingot of a diameter which is one size larger than the size of the substrates to be fabricated, that is, 4 mm to 12 mm in range, is preferable. The 4 mm of the lower limit side of the plus part of this substrate size means the minimum required processing margin when processing the substrates, while conversely the 12 mm of the upper limit side of the plus part of the substrate side is set since if becoming greater than that, the processing cost will end up becoming excessive. Therefore, in the same way as the case of a 6 inch or more substrate-use ingot, it should be made one size larger than the size of the substrates to be prepared, that is, 4 mm to 12 mm in range. However, in the case of a 6 inch or more substrate-use ingot, from the viewpoint of improving the productivity of devices, it is desirable to increase the diameter of the substrate. In this sense, there is no upper limit, but with current manufacturing technology, if the diameter of the ingot is over 300 mm, crystal growth itself is difficult. Simultaneously, the processing costs become massive. For example, the substrate costs per chip end up conversely rising. For this reason, in the case of a 6 inch or more substrate-use ingot, the upper limit of the diameter of the ingot grown is preferably 300 mm or less.

Note that, in the present invention, when evaluating the dislocation density and Raman index, any SiC single crystal substrate was cut out from at least a part having a relative height position of 0.2 to 0.8 or 0.2 to 0.9 in range in the height direction of the ingot, the substrate was processed by a known method, and the evaluation was conducted in the mirror polished state. Further, the dislocation densities of BPDs and TSDs were measured by etching by molten KOH and observation by an optical microscope. Details are as described in the examples.

In the present invention, as explained above, as the reason why an SiC single crystal ingot excellent in crystal quality and small in elastic strain is obtained, in the modified Lely method, “1) control of the heat input from the side surfaces of the ingot during crystal growth to suppress as much as possible a change in temperature distribution of the ingot during crystal growth” and “2) growing the crystal by making the temperature gradient of the crystal growth direction relatively small while maintaining the degree of supersaturation of the vapor consisting of Si and C sublimated from the sublimation materials at the growth surface” may be mentioned. These will be explained below.

First, “1) control of the heat input from the side surfaces of the ingot during crystal growth to suppress as much as possible a change in temperature distribution of the ingot during crystal growth” (below, referred to as “the action of 1)”) was studied in the above PTL 6. It is believed that internal stress of the SiC single crystal ingot, which finally becomes dislocations or elastic strain, occurs at the growth surface at the time of growth of the SiC single crystal and, not only this, increases due to a change in the temperature distribution of the crystal after growth. That is, at a certain time during growth, an SiC single crystal ingot is in a state where internal stress occurs due to the temperature distribution at that point of time. Part of the internal stress is already converted to dislocations. If growth is completed while the temperature distribution at this time is maintained as is, it is possible to produce an SiC single crystal substrate having dislocation densities and elastic strain reflecting this temperature distribution.

However, under actual manufacturing conditions, the temperature distribution changes due to several reasons along with crystal growth and new stress occurs in the SiC single crystal ingot. Due to this newly generated stress, the BPDs proliferate. Further, due to changes in the atomic array at the growth surface. TSDs are caused. Further, the elastic strain also ends up increasing.

Therefore, the heat input from the side surfaces of the ingot during crystal growth is controlled so as to suppress a change in the temperature distribution of the ingot during crystal growth and thereby to suppress proliferation of BPDs and TSDs during growth and reduce elastic strain. Specifically, the following three means may be mentioned. Any one of these means may be employed for crystal growth of the SiC single crystal or two or more may be combined for crystal growth. Note that, in actual SiC single crystal growth, it is impossible to actually measure the state inside the 2000° C. or more crucible. Other than using the finite element method to analyze the temperature and internal stress of the ingot and, further, building up evaluations of quality of actually obtained SiC single crystals, there is no means to suppress proliferation of BPDs and TSDs during growth and reduce elastic strain at the present point of time. It is difficult to quantitatively express the state of heat input of the side surfaces of the ingot during crystal growth.

As the first means according to the “action of 1)”, before crystal growth, the insulating material for surrounding the area around the crucible is heat treated by a 2250° C. or more, preferably 2450° C. or more temperature, then the SiC single crystal is grown in the crucible. This is to deal with the fluctuation in input heat from the side surfaces of the ingot due to the deterioration of characteristics of the insulating material arranged at the outside of the crucible for crystal growth—one of the causes of a change in the temperature distribution in the ingot.

In general, as the insulating material used for production of an SiC single crystal by the sublimation recrystallization method, graphite felt or a graphite shaped insulating material is often used. At the time of manufacture of these, the temperature for heat treatment is usually 1000° C. or less. Even for high temperature treated parts, it is at a maximum 2000° C. In this regard, however, at the time of growth of an SiC single crystal, the crucible becomes a maximum of 2400° C. or more, and graphitization of the insulating material and other reactions occur during crystal growth, so the heat insulating characteristic falls. Further, the sublimation gas component leaks from the inside of the crucible. That component causes a thermochemical reaction with the insulating material to degrade the graphite whereby again the insulating characteristic falls. In addition, along with deterioration of this insulating material, due to temperature feedback in the control of the device when actually producing an SiC single crystal ingot, if the current input to the induction heating coil rises, it is judged that the crucible temperature has fallen due to a drop in the insulation characteristic. As a result, a temperature difference occurs between the parts where the progress in degradation is slight and the parts where the degradation is advanced. This temperature difference has an effect on the temperature distribution inside the ingot and ends up leading to the generation of new internal stress.

Therefore, by heat treating the insulating material in advance to raise the degree of graphitization of the graphite fiber etc., the occurrence of such a change in temperature distribution of the ingot during crystal growth is suppressed. As heat treatment of this insulating material, for example, it is also possible to heat treat just the insulating material in a separate inert atmosphere and possible to follow the same procedure as at the time of crystal growth to attach it to the crucible, then heat treat it by induction heating before crystal growth. Note that, the upper limit of the temperature of the heat treatment performed in advance of this can be made 3000° C. from the viewpoints of the graphite itself ending up sublimating and the effects becoming saturated.

Further, as the second means relating to the “action of 1)”, for example, a member with a high heat conductivity (below, referred to as a “heat flux control member”) is arranged around the seed crystal attachment region of the crucible lid to which the seed crystal is to be attached, and the heat flowing from the crucible to the heat flux control member is increased so as to reduce the heat flux from the crucible to the ingot side walls and, further, from the ingot to the seed crystal attachment region and suppress a change in temperature distribution of the ingot during crystal growth. Another major reason causing a change in temperature distribution of the ingot during crystal growth is the change in amount of heat of the ingot due to the flow of heat from the high temperature material side to the low temperature seed crystal side passing through the graphite member forming the crucible and entering the side surfaces of the ingot. Along with the growth of the SiC single crystal, the side surfaces of the ingot increase in area, so such a flow of heat cannot be ignored. This second means suppresses the change in temperature distribution of the ingot due to the above-mentioned flow of heat.

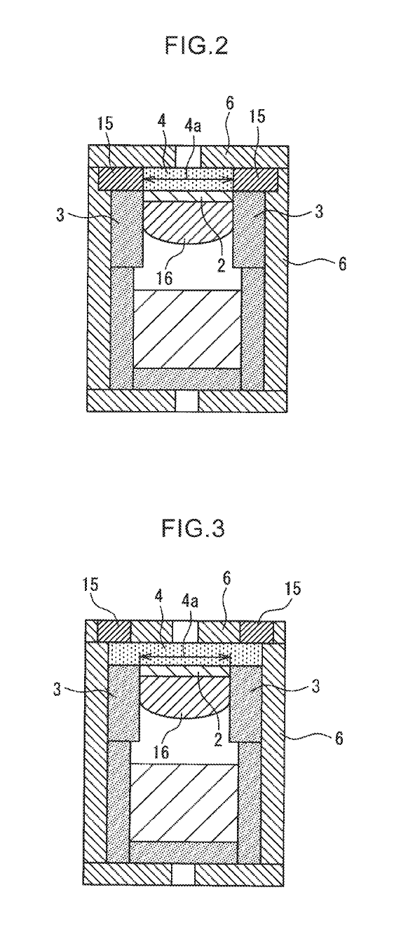

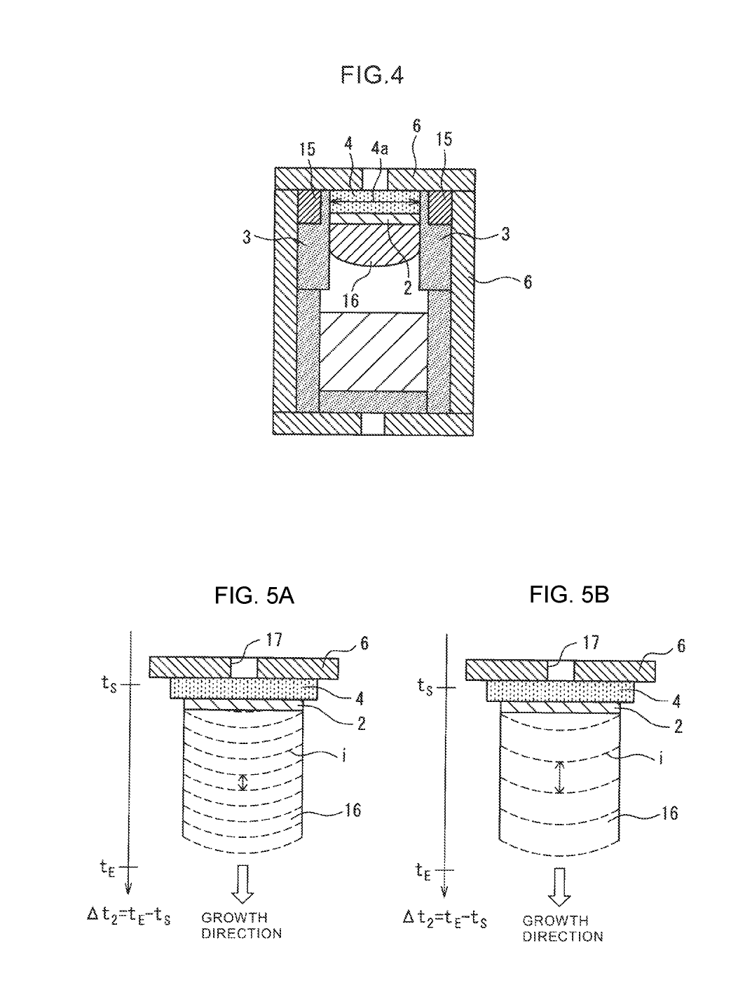

Here, the method of attachment of the heat flux control member is not particularly limited. For example, as shown in FIG. 2, the crucible lid 4 comprises the two members of the member forming the seed crystal attachment region 4a and the heat flux control member 15 surrounding this. Furthermore, it is also possible to use a member with a higher heat conductivity than the member forming the seed crystal attachment region 4a so as to form the heat flux control member 15 and to control the heat input from the side surfaces of the ingot 16 during crystal growth. Further, as shown in FIG. 3, it is also possible to use part of the insulating material covering the outside of the crucible lid 4 as the heat flux control member 15 and surround the area around the seed crystal attachment region 4a of the crucible lid 4 or, as shown in FIG. 4, place the heat flux control member 15 at part of a side wall part of the crucible body 3 and surround the area around the seed crystal attachment region 4a of the crucible lid 4 by the heat flux control member 15.

The heat conductivity of the heat flux control member preferably satisfies the relationship of 1.1×λ₁≤λ₂ where the room temperature heat conductivity of the member forming the seed crystal attachment region is λ₁ and the room temperature heat conductivity of the heat flux control member is λ₂. More preferably, 1.2×λ₁≤λ₂. Specifically, when the member forming the seed crystal attachment region at the crucible lid is comprised of isotropic graphite, for example, it is possible to use a heat flux control member comprised of pitch-impregnated graphite or CVD graphite etc. Note that, if the room temperature heat conductivity λ₂ of the heat flux control member is over 1.8 times the room temperature heat conductivity λ₁ of the member forming the seed crystal attachment region, a large change ends up occurring in the temperature distribution at the growth surface, and it seems difficult to grow an SiC single crystal ingot stably. Therefore, this value can be made the upper limit of the ratio of these.

Furthermore, as the third means relating to the “action of 1)”, the heat conductivity of the atmospheric gas at the peripheral space of the crucible for crystal growth set inside the double quartz tube is improved and the amount of heat radiated from the crucible to the inside of the atmosphere is increased. Here, as the high heat conducting gas component, in general, hydrogen is well known, but hydrogen has effects such as etching the graphite or SiC by which the crucible is formed, so helium or another rare gas should be used. Specifically, when introducing 10 vol % or more of helium into the atmosphere of the peripheral space formed between the crucible covered by the insulating material and the double quartz tube, the intended effect is obtained. A larger effect than the case where the helium is 20 vol % or more is obtained. The upper limit of the concentration of helium can be determined from not only the costs, but also the relationship with the electrical conductivity sought from the SiC single crystal (that is, concentration of dopant in atmosphere), but if the concentration of helium gas becomes 50 vol % or more, even in this case, a large change is liable to occur in the temperature distribution of the growth surface and stable growth is liable to become difficult. This value becomes the substantive upper limit value.

Next, “2) growing the crystal by making the temperature gradient of the crystal growth direction relatively small while maintaining the degree of supersaturation at the growth surface of the vapor comprised of Si and C sublimated from the sublimation materials” (below, referred to as the “action of 2)”) is based on the following thinking. In general, in the modified Lely method, the shape of the growth surface of the growing SiC single crystal may be determined by controlling the temperature distribution near the growth surface. Usually, the temperature distribution is controlled so that the crystal growth end of the front end of the ingot has a convex shape. In more detail, an isotherm of a suitable convex shape is formed toward the growth direction in the growth space so that the difference (Δt₁=t_{P}−t_{C}) between the temperature t_{P} of any point at the growth surface at an edge part of the grown crystal and the temperature t_{C} of the center part of the ingot with an equal distance from this point and the seed crystal becomes positive. This is so as to enable crystal growth at the crystal growth surface from the center part to the edge part and thereby control the formation of polycrystals and simultaneously cause stable growth of the targeted polytype and produce a good quality, single polytype SiC single crystal ingot with few defects.

In this regard, when the temperature difference Δt₁ in the plane vertical to the growth direction becomes larger, the internal stress caused in the single crystal will increase. That is, the strength of the convexity and the strength of the internal stress are correlated. In particular, when the internal stress at edge part of the ingot (component in circumferential direction) increases and the crystal becomes large in diameter, the absolute value of the internal stress ends up becoming larger along with this. That is, attaining both a good quality SiC single crystal with few defects and reduction of the occurrence of internal stress is extremely difficult.

Therefore, the inventors studied suppressing the formation of internal stress by maintaining the convex shape of the crystal growth surface while making the temperature gradient Δt₂ in the crystal growth direction relatively small. If showing this point by a schematic view, the result becomes as shown in FIGS. 5A and 5B. FIG. 5B shows the state where the temperature gradient Δt2 in the crystal growth direction is smaller than FIG. 5A. The convex shapes of the isotherms I are the same, but when cutting out SiC single crystal substrates having the particular thicknesses vertical to the growth direction (bold arrow direction in figure), the intervals of the isotherms in the crystal growth direction and the intervals of the isotherms from the center parts to the edge parts of the substrates both become wider in FIG. 5B. That is, the ingot 16 of FIG. 5B is decreased in internal stress compared with the ingot 16 of FIG. 5A.

However, if the temperature gradient in the crystal growth direction becomes smaller, in general, there is the danger that the speed of crystal growth will end up falling and the degree of supersaturation at the growth surface will become excessively small, single polytype growth will be inhibited, and other growth abnormalities will be caused. Therefore, the crystal is grown so as to maintain the degree of supersaturation at the growth surface of vapor consisting of Si and C sublimating from the sublimation materials. As the method of maintaining this degree of supersaturation, for example, i) the method of lowering the frequency of the induction heating current and reducing the thickness of the side walls of the crucible body in which the sublimation materials are filled to directly heat by induction the sublimation materials themselves to raise them in temperature and promote sublimation, ii) the method of lowering the control pressure in the growth space and promoting the diffusion of the sublimation gas to increase the amount of sublimation materials reaching the growth surface, iii) the method of increasing the amount of sublimation materials filled to increase the total surface area of the materials in the crucible body and thereby increase the amount of sublimation under the same temperature conditions, etc. may be mentioned.

Further, as the method of making the temperature gradient Δt₂ of the crystal growth direction relatively small, it is possible to directly adjust the temperature t_{E} at the sublimation material side and the temperature t_{S} of the seed crystal side heated by the induction heating coil so as to make the temperature difference Δt₂ smaller than the past. In addition to this, for example, the method of adjusting the size of a heat removal hole 17 of the insulating material 6 arranged at the crucible lid 4 to which the seed crystal is attached to make the temperature t_{S} of the seed crystal side a relatively high temperature or enlarge a temperature measurement hole of the bottom part of the crucible body to make the sublimation material side relatively low in temperature. Further, the specific value of this temperature gradient Δt₂ fluctuates depending on the size of the crucible for crystal growth, the thickness of the side walls of the crucible body, and also the type and thickness of the insulating material etc., so it is difficult to completely control the temperature gradient Δt₂. However, for example, when producing an ingot for yielding diameter 4 inch SiC single crystal substrates, in the past methods, by setting the temperature difference Δt₂ to become 250° C., while in the present invention, by setting the temperature difference Δt₂ to 90 to 210° C., it is possible to make the BPD density observed at the surface of an SiC single crystal substrate cut out from a part with a relative height position of at least 0.2 to 0.8 in range a density of 500/cm² or less and make the TSD density at the surface of the SiC single crystal substrate a density of 300/cm² or less.

Further, according to the present invention, when producing an ingot for yielding diameter 4 inch SiC single crystal substrates, by setting the temperature difference Δt₂ so as to become 140 to 210° C., it is possible to make the BPD density observed at the surface of an SiC single crystal substrate cut out from a part with a relative height position of at least 0.2 to 0.9 in range a density of 500/cm² or less and make the TSD density a density of 300/cm² or less.

In the present invention, the temperature gradient in the crystal growth direction is made smaller while the degree of supersaturation at the growth surface is maintained so as to obtain substantive crystal growth of the same extent as the past methods. Preferably, the degree of supersaturation is maintained so that the speed of growth becomes 0.10 mm/h to 0.60 mm/h. More preferably, the degree of supersaturation is maintained so that the speed of growth becomes 0.15 mm/h to 0.60 mm/h.

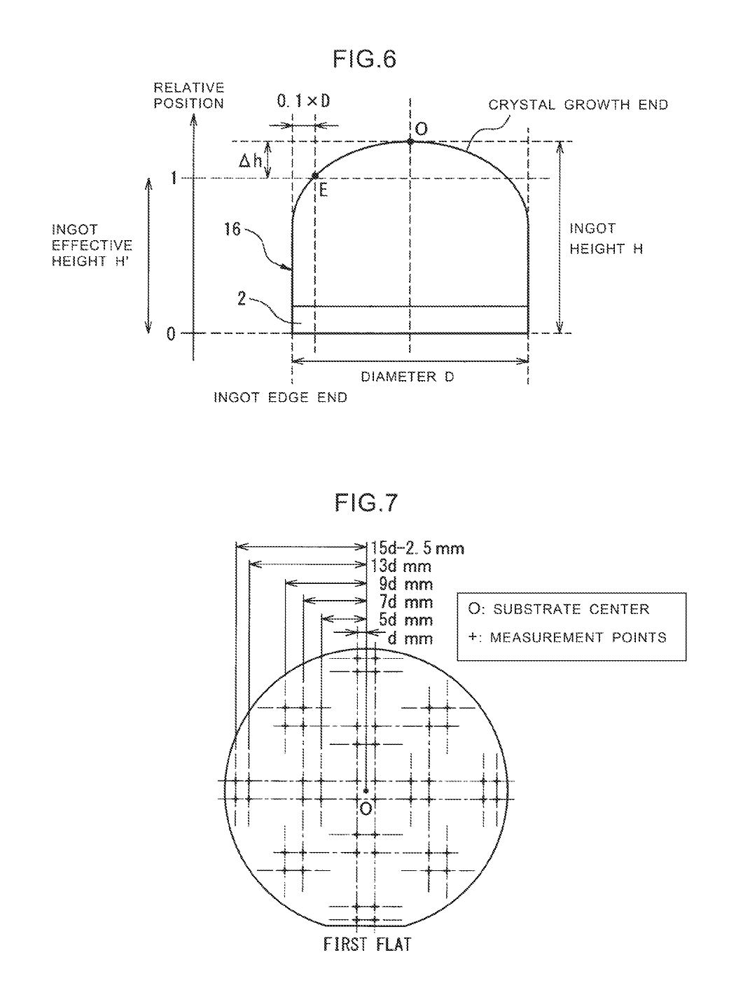

Further, the obtained SiC single crystal ingot is made to have a convex shape of the same extent as the past methods. Preferably, as shown in FIG. 6, the crystal growth end of the front end of the ingot is made to have a convex shape so that the difference of height Δh (=O−E) between the center point O of the crystal growth end corresponding to the position of the front end of the ingot and the edge point E on the crystal growth end corresponding to a position inside from a side surface of the ingot by 10% of the diameter becomes 1 mm to 7 mm. Furthermore, the height H of the ingot is preferably 25 mm or more in the case of a less than 6 inch substrate-use ingot and 35 mm or more in the case of a diameter 6 inch or more substrate-use ingot in the state before shaping (as-grown). The upper limits of these ingot heights are not particularly limited, but the crucible has to be enlarged in order to increase the sublimation materials able to be charged for a growing each crystal. This is disadvantageous cost wise. If considering this etc., at the present point of time, substantively, 100 mm is the upper limit value. Note that, the height H of the ingot referred to here includes the seed crystal.

According to the present invention, it is possible to obtain an SiC single crystal ingot with low dislocation densities of basal plane dislocations and threading screw dislocations, excellent crystal quality, and small elastic strain with a good productivity. Further, it is possible to make it one with a substantially single polytype, for example, it is possible to obtain a good quality 4H type SiC single crystal ingot which is suitable for electronic devices. For this reason, it becomes possible to prepare a high performance SiC device from the SiC single crystal ingot of the present invention and is possible to secure a high yield even when fabricating devices on an industrial scale.

### EXAMPLES

Below, the present invention will be specifically explained based on examples etc. Note that, the present invention is not limited to the contents of these.

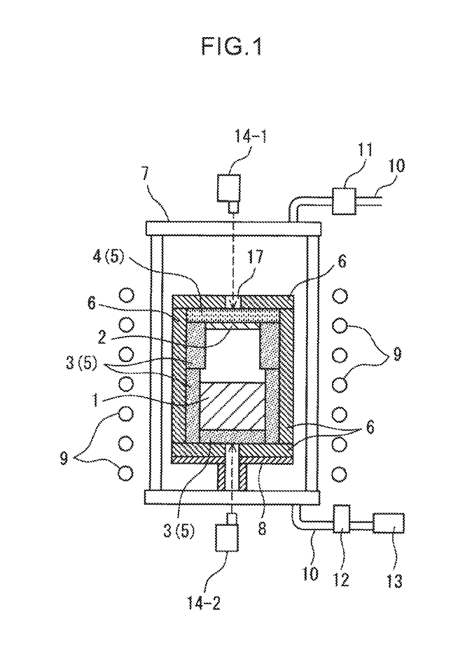

First. FIG. 1 schematically shows the single crystal growth apparatus used for production of an SiC single crystal ingot according to the present invention. In the examples and comparative examples, sublimation materials 1 were made to sublimate by induction heating under the following conditions to make them recrystallize on a seed crystal 2 to grow a crystal by the modified Lely method. In this apparatus, the seed crystal 2 was attached to the inside of a crucible lid 4 made of graphite which constitute a crucible 5 for crystal growth. The sublimation materials 1 were filled inside a graphite crucible body 3. This graphite crucible 5 was covered therearound by an insulating material 6 so as to be shielded it against heat, was placed inside a double quartz tube 7, and was set on a graphite support pedestal 8.

Further, using a vacuum exhaust device 12 and pressure control device 13, the inside of the double quartz tube 7 was evacuated to less than 1.0×10⁻⁴ Pa, then purity 99.9999% or more high purity Ar gas was introduced to the inside of the double quartz tube 7 through piping 10 while controlled by a mass flow controller 11. The vacuum exhaust device 12 and pressure control device 13 were used to hold the inside of the double quartz tube at a predetermined pressure while running a high frequency current to a work coil 9 for induction heating to raise the temperature of the bottom part of the crucible body to the target temperature. In the same way for the nitrogen gas (N₂) as well, the N₂ gas was introduced through the piping 10 while controlled by the mass flow controller 11. The nitrogen partial pressure in the atmospheric gas was controlled to adjust the concentration of the nitrogen element taken into the SiC crystal. Here, the crucible temperature was measured using a radiant thermometer 14 through diameter 2 to 15 mm light paths provided at the insulating material 6 on the top part of the crucible lid 4 and the insulating material 6 at the bottom part of the crucible body 3, the top temperature of the crucible lid 4 (temperature according to radiation thermometer 14-1) was used as the seed crystal temperature, and the bottom temperature of the crucible body 3 (temperature according to radiation thermometer 14-2) was used as the material temperature. After this, the pressure inside the double quartz tube 7 was reduced to the growth pressure. This state was maintained for a predetermined time to grow the crystal.

### Example 1: Invention Example of Ingot for Diameter 4 to 6 Inch or More Substrate

Example 1 is an invention example of a diameter 4 inch to less than 6 inch substrate-use ingot. To produce Example 1, to control the heat input from the side surfaces of the ingot during crystal growth to suppress a change in temperature distribution of the ingot during crystal growth as much as possible (that is, to obtain the “action of 1)”), the previously shown first means and second means were employed. Further, to grow the crystal while making the temperature gradient in the crystal growth direction relatively small and maintaining the degree of supersaturation at the growth surface (that is, to obtain the “action of 2)”), the crystal was grown by making the temperature gradient Δt₂ in the crystal growth direction smaller than the conventional methods while lowering the control pressure in the growth space and promoting the diffusion of the sublimation gas to increase the amount of sublimation materials reaching the growth surface (that is, using the above method ii)). The specific production conditions of Example 1 were as follows:

First, one set of commercially available graphite felt (one heat treated in advance at 2000° C.) was prepared. This graphite felt was heat treated in a high purity argon atmosphere at 2300° C. for 12 hours and was used as the insulating material 6. Further, as shown in FIG. 2, the crucible lid 4 having an integral structure wherein the area around the seed crystal attachment region 4a to which the seed crystal 2 was attached was surrounded by a heat flux control member 15 was used. Here, a seed crystal attachment region 4a is formed from an isotropic graphite material (room temperature heat conductivity 125 w/m·K) having a diameter of 101 mm. Further, the heat flux control member 15 was made a donut shape of a diameter of 130 mm of a circular shape concentric with this seed crustal attachment region 4a, and it was formed from a pitch-impregnated graphite material (room temperature heat conductivity of 150 w/m·K).

A seed crystal substrate (thickness 1200 μm) of an SiC single crystal consisting of a 4H type single polytype having the main surface of the (0001) face, having a <0001> axis slanted 4° in the <11-20> direction, and having a diameter of 101 mm was used as the seed crystal 2. This seed crystal substrate was attached to the seed crystal attachment region 4a of the above-mentioned crucible lid 4. The crucible body 3 was filled with about 1600 g of SiC powder as a sublimation material. The area around the crucible 5 was covered by the above heat treated graphite felt, and the assembly of the single crystal growth apparatus shown in FIG. 1 was completed.

Next, as explained above, the inside of the double quartz tube 7 was evacuated, then high purity Ar gas was introduced to the inside of the double quartz tube 7. While maintaining the pressure inside the quartz tube at a 0.67 kPa pressure that was lower than the pressure of usual growth, the divided pressure of the nitrogen gas was made to change in 180 Pa to 90 Pa in range, and the optimum conductivity was maintained in the ingot as a whole at the time of crystal growth. Further, a high frequency current was run through a work coil 9 so that the top temperature of the crucible lid 4 became 2100° C. and the bottom temperature of the crucible body 3 became 2200° C. The temperature difference Δt₂ of the seed crystal temperature and the material temperature at this time was 150° C. This temperature difference again becomes a condition for the temperature difference being smaller than usual growth.

The SiC single crystal ingot according to Example 1 was produced by holding this state for 80 hours. Note that, the temperature difference Δt₂ of the seed crystal temperature and the material temperature is a value found by simulation of actual production. The same also applies to the following examples and comparative examples.

The SiC single crystal ingot of Example 1 obtained in the above way had a crystal growth end of a convex shape of the front end thereof, a diameter D of 107.1 mm, and a height H′ of an edge point E (as shown in FIG. 6, point E on crystal growth end at position inside from a side surface of the ingot toward the center by 10% of the diameter (diameter D)) (effective height H′) of 32.2 mm. Further, the height H of the ingot of Example 1 (height of center point O at crystal growth end) was 36.4 mm, while the difference “h” of height of the center point O and edge point E was 4.3 mm. Further, the SiC single crystal ingot of Example 1 was identified for polytype of the surface by a spectrum of Raman spectroscopy. Still further, by observation of the appearance, it was confirmed that there were also no sub grain boundaries and other macro defects in this invention example, so it was learned that Example 1 had a 4H type single polytype.

The SiC single crystal ingot of Example 1 was processed, as shown in FIG. 6, in the following way to fabricate eight diameter 4 inch SiC single crystal substrates from relative height positions with respect to the height direction of the ingot of 0.2 to 0.9 in range when defining a bottom surface at the seed crystal side as zero and defining a height of an edge point E as “1”.

That is, the SiC single crystal ingot of Example 1 was ground down in outer shape, then a multi-wire saw was used to cut out plate-shaped substrates from the Si single crystal ingot of Example 1. Next, a diamond abrasive was used to polish the plate-shaped substrates. Finally, these were buffed by an average particle size 0.25 μm diamond abrasive to fabricate diameter 100 mm, thickness 0.4 mm mirror surface substrates each having a (0001) face with an off angle of 4° the same as the seed crystal. At this time, the processed, finished substrate taken from a position of a relative height position of 0.2 with respect to the height direction of the SiC single crystal ingot was made the No. 11 substrate, and the substrate from a relative height position of 0.3 was made the No. 12 substrate. In this manner, the No. 11 to No. 18 SiC single crystal substrates were obtained in increments of 0.1 (seed crystal side being 11th substrate and ingot tip side being the No. 18 substrate).

The No. 11 to No. 18 SiC single crystal substrates fabricated from the SiC single crystal ingot of Example 1 were, first, measured for Raman shift using a Raman spectrometer (NRS-7100 made by JASCO, resolution±0.05 cm⁻¹). The light source for this Raman measurement was a 532 nm green laser. This was irradiated at a 42 μm spot at the surface of the sample of the SiC single crystal substrate. For one measurement location, measurement light was irradiated at a total of 72 points of a horizontal 8 rows and vertical 9 columns at spot intervals of 10 μm. The average value of the measurement lights at these points was defined as the scattered light data of the measurement location. For one substrate, the center of one measurement location is the center of the substrate (center part A of substrate), while the center of another measurement location is a position separated from the edge of the substrate by 2 mm in the center direction (position at inside from edge by 2 mm on diameter) (edge part B of substrate). The wavelength of the Raman scattered light was measured for these two locations. Further, the difference of the wave numbers (reciprocal of wavelength) (that is, the difference (A−B) of the Raman Shift value (A) measured at the center part of the substrate and the Raman Shift value (B) measured at an edge part) was made the Raman index. The results are shown in Table 1.

Further, the No. 11 to No. 18 SiC single crystal substrates fabricated from the SiC single crystal ingot of Example 1 were etched by molten KOH and measured for BPD density and TSD density by an optical microscope. Here, in accordance with the method described in J. Takahashi et al., Journal of Crystal Growth, 135 (1994), 61-70, the substrates were immersed in 530° C. molten KOH for 10 minutes. The dislocation defects were classified from the shapes of the etch pits with shell-shaped etch pits classified as BPDs and medium and large sized hexagonal shaped etch pits classified as TSDs.

Here, as the method of calculation of the dislocation density, as shown in FIG. 7. 52 points on the substrate in a symmetrical relationship at the top and bottom and left and right in the figure were counted. The TSDs were counted in a 2073 μm×1601 μm measurement area and the BPDs and other dislocations besides the TSDs were counted in a 663 μm×525 μm measurement area so that these counted points became the centers of the measurement areas, and the average values were made the dislocation densities of the substrates. Further, the size of the etch pits due to the TSDs was larger than the size of the etch pits due to the BPDs, so the measurement area for counting the TSDs was made broader than the measurement area for counting the BPDs. Further, the value of “d” shown in FIG. 7 was made 3.25 mm for a 100 mm (diameter 4 inch) substrate such as in Example 1, but was made 4.8 mm for the later explained 150 mm (diameter 6 inch) or more substrate. Aside from these as well, by selecting a suitable “d”, it is possible to accurately evaluate the dislocation density without being affected by the diameter.

The results of measurement of the dislocation densities of the No. 11 to No. 18 SiC single crystal substrates prepared from the SiC single crystal ingot of Example 1 are shown in Table 1.

TABLE 1

| | | | TSD | Sum of BPD |
|---|---|---|---|---|
| Substrate no. | | BPD density | density | density and |
| (relative height) | Raman index | (/cm²) | (/cm²) | TSD density |
| 11 (0.2) | 0.09 | 490 | 270 | 760 |
| 12 (0.3) | 0.08 | 410 | 230 | 640 |
| 13 (0.4) | 0.08 | 280 | 240 | 520 |
| 14 (0.5) | 0.07 | 150 | 200 | 350 |
| 15 (0.6) | 0.06 | 140 | 190 | 330 |
| 16 (0.7) | 0.06 | 160 | 180 | 340 |
| 17 (0.8) | 0.04 | 140 | 200 | 340 |
| 18 (0.9) | 0.04 | 170 | 210 | 380 |

Regarding the growth conditions of the SiC single crystal in this Example 1, the temperature difference between the seed crystal side and sublimation material side is made relatively small, but by lowering the growth pressure, a speed of growth equal to that of the past can be secured and the same extent of ingot height can be obtained. Further, the convex shape of the crystal growth surface is equivalent to that of the past, so stability of the polytype can be secured. In addition, as will be understood from the results shown in Table 1, according to such crystal growth, the temperature difference in the vertical direction of the obtained ingot (crystal growth direction) and in the plane in the horizontal direction vertical to this becomes small, the internal stress is decreased, each dislocation density is low, and production of an SiC single crystal ingot with a small Raman index (elastic strain) is believed to become possible.

### Example 2: Invention Example for Ingot for Diameter 6 Inch or More Substrate

Next, growth of a single crystal of Example 2 will be explained. The technical idea of crystal growth of Example 2 is similar to Example 1. To control the heat input from the side surfaces of the ingot during crystal growth and suppress a change in temperature distribution of the ingot during crystal growth as much as possible (that is, to obtain the above “action of 1)”), the previously shown first means and second means were employed. Further, to grow the crystal by making the temperature gradient in the crystal growth direction relatively small while maintaining the degree of supersaturation of the growth surface (that is, to obtain the “action of 2)”), the crystal is grown by making the temperature gradient Δt₂ in the crystal growth direction smaller than the past methods while lowering the control pressure of the growth space and promoting the diffusion of the sublimation gas to increase the amount of sublimation materials reaching the growth surface (that is, using the above method ii)). However, in Example 2, a diameter over 150 mm single crystal ingot was produced. The specific production conditions of Example 2 were as follows:

First, one set of commercially available graphite felt (one heat treated in advance at 2000° C.) was prepared. This graphite felt was heat treated in a high purity argon atmosphere at 2550° C. for 16 hours and was used as an insulating material 6. Further, for the crucible lid 4, as shown in FIG. 2, an integrally formed one where the area around the seed crystal attachment region 4a to which the seed crystal 2 was attached was surrounded by the heat flux control member 15 was used. Here, the seed crystal attachment region 4a was formed from an isotropic graphite material (room temperature heat conductivity 125 w/m·K) having a diameter of 155 mm. Further, the heat flux control member 15 was made a donut shape of a diameter of 130 mm of a circular shape concentric with this formed from a pitch-impregnated graphite material (a material further raised in bulk density from the pitch-impregnated graphite material of Example 1 and having a room temperature heat conductivity of 150 w/m·K).

As the seed crystal 2, a seed crystal substrate (thickness 1400 μm) of an SiC single crystal comprised of a 4H type single polytype having the (0001) face as its main surface, having a <0001> axis slanted 4° in the <11-20> direction, and having a diameter of 154 mm was used. This was attached to the seed crystal attachment region 4a of the above-mentioned crucible lid 4. The crucible body 3 was filled with about 3300 g of SiC powder as a sublimation material. The area around the crucible 5 was covered by the above heat treated graphite felt to thereby complete the assembly of the single crystal growth apparatus shown in FIG. 1.

Next, a single crystal ingot was produced under conditions substantially the same as Example 1. During growth, the inside of the quartz tube was maintained at a pressure of 0.67 kPa, lower than usual growth, while the partial pressure of the nitrogen gas was changed from 180 Pa to 90 Pa in range so that the optimum conductivity was maintained at the ingot as a whole during crystal growth. Further, high frequency current was run through the work coil 9 so that the top temperature of the crucible lid 4 became 2100° C. and the bottom temperature of the crucible body 3 became 2150° C. The temperature difference Δt2 between the seed crystal temperature and material temperature at this time was 145° C. This again is a condition for the temperature difference being smaller than usual growth. This state was held for 100 hours to produce the SiC single crystal ingot according to Example 2.

The SiC single crystal ingot of Example 2 obtained in the above way had a crystal growth end of the front end of the ingot of a convex shape, a diameter D of 157.7 mm, and a height H′ of the edge point E of 38.3 mm. Further, the height H of the ingot of Example 2 was 41.2 mm, while the difference “hi” of height of the center point O and edge point E was 2.9 mm. Further, the SiC single crystal ingot of Example 2 was identified for polytype of the surface by the spectrum of Raman spectroscopy. Still further, by observation of the appearance, it was confirmed that there were also no sub grain boundaries and other macro defects in this invention example, so it was learned that Example 2 had a 4H type single polytype.

From the SiC single crystal ingot of Example 2, eight mirror surface substrates having relative height positions in the ingot in the same way as Example 1, diameters of 150 mm, and thicknesses of 0.4 mm were processed (No. 21 to No. 28 substrates counting in order from the seed crystal side, relative height positions 0.2 to 0.9 in range) and evaluated for quality. The results of evaluation of quality of the substrate obtained from the SiC single crystal ingot of Example 2 are shown in Table 2. As will be understood from Table 2, in this Example 2 as well, an SiC single crystal ingot with low dislocation densities and a small Raman index (elastic strain) was obtained.

TABLE 2

| | | | TSD | Sum of BPD |
|---|---|---|---|---|
| Substrate no. | | BPD density | density | density and |
| (relative height) | Raman index | (/cm²) | (/cm²) | TSD density |
| 21 (0.2) | 0.13 | 440 | 210 | 650 |
| 22 (0.3) | 0.11 | 140 | 180 | 320 |
| 23 (0.4) | 0.09 | 130 | 130 | 260 |
| 24 (0.5) | 0.07 | 90 | 130 | 220 |
| 25 (0.6) | 0.06 | 80 | 130 | 210 |
| 26 (0.7) | 0.05 | 80 | 110 | 190 |
| 27 (0.8) | 0.04 | 80 | 120 | 200 |
| 28 (0.9) | 0.03 | 70 | 110 | 180 |

### Example 3: Invention Example of Ingot for Diameter 6 Inch or More Substrate

Next, growth of a single crystal of Example 3 will be explained as an example of the invention of a diameter 6 inch or more substrate-use ingot. The technical idea of crystal growth of Example 3 is similar to Example 1. To control the heat input from the side surfaces of the ingot during crystal growth and suppress a change in temperature distribution of the ingot during crystal growth as much as possible (that is, to obtain the above “action of 1)”), the previously shown first means and second means were employed. Further, to grow the crystal by making the temperature gradient in the crystal growth direction relatively small while maintaining the degree of supersaturation of the growth surface (that is, to obtain the “action of 2)”), the crystal was grown by making the temperature gradient Δt₂ in the crystal growth direction smaller than the conventional method while lowering the control pressure of the growth space and promoting the diffusion of the sublimation gas to increase the amount of sublimation materials reaching the growth surface (that is, using the above method ii)). In Example 3, a single crystal ingot for obtaining a diameter 100 mm substrate was produced.

First, one set of commercially available graphite felt (one heat treated in advance at 2000° C.) was prepared. This graphite felt was heat treated in a high purity argon atmosphere at 2550° C. for 48 hours and was used as the insulating material 6. Further, for the crucible lid 4, as shown in FIG. 2, an integrally formed one where the area around the seed crystal attachment region 4a to which the seed crystal 2 was attached was surrounded by the heat flux control member 15 was used. Here, the seed crystal attachment region 4a was formed from an isotropic graphite material (room temperature heat conductivity 125 w/m·K) having a diameter of 106 mm. Further, the heat flux control member 15 was made a donut shape of a diameter of 94 mm of a circular shape concentric with this formed from a pitch-impregnated graphite material (same material as Example 2 with room temperature heat conductivity of 150 w/m·K).

In this Example 3, to prevent deterioration of the insulating material by leakage of sublimation gas from the inside of the crucible, the fastening parts of the members forming the crucible (crucible body and lid) were bonded together using a commercially available graphite-use adhesive (Graphi-Bond made by Aremco etc.) to eliminate the causes of gas leakage as much as possible. However, structural parts designed to intentionally pass gas were not bonded. By suppressing unintentional gas leakage in this way, a change of the temperature gradient due to deterioration of the insulating material was suppressed and the change in the temperature field of the crystal became further smaller.

Further, in this Example 3, as the seed crystal 2, a seed crystal substrate (thickness 1200 μm) of an SiC single crystal comprised of a 4H type single polytype having the (0001) face as its main surface, having a <0001> axis slanted 4° in the <11-20> direction, and having a diameter of 102 mm was used. This was attached to the seed crystal attachment region 4a of the above-mentioned crucible lid 4. The crucible body 3 was filled with about 2300 g of SiC powder as a sublimation material. The area around the crucible 5 was covered by the above heat treated graphite felt to thereby complete the assembly of the single crystal growth apparatus shown in FIG. 1.

Next, a single crystal ingot was produced. During growth, the inside of the quartz tube was maintained at a pressure of 0.40 kPa, lower than usual growth, while the partial pressure of the nitrogen gas was changed from 180 Pa to 90 Pa in range so that the optimum conductivity was maintained at the ingot as a whole during crystal growth. Further, high frequency current was run through the work coil 9 so that the top temperature of the crucible lid 4 became 2100° C. and the bottom temperature of the crucible body 3 became 2125° C. The temperature difference Δt2 between the seed crystal temperature and material temperature at this time was 125° C. This again is a condition for the temperature difference being smaller than usual growth. This state was held for 150 hours to produce the SiC single crystal ingot according to Example 3.

The SiC single crystal ingot obtained in the above way had a crystal growth end of the front end of the ingot with a convex shape, a diameter D of 108.5 mm, and a height H′ of an edge point E of 55.6 mm. Further, the height H of the ingot was 57.4 mm, while the difference “h” of height of the center point O and edge point E was 1.8 mm. Further, it was learned that the obtained SiC single crystal ingot had a 4H type single polytype when identifying the polytype of the surface by the spectrum of Raman spectroscopy and further that there were also no sub-grain boundaries and other macro defect by observation of the surface.

From the obtained SiC single crystal ingot, eight mirror surface substrates having relative height positions in the ingot in the same way as Example 1, diameters of 100 mm, and thicknesses of 0.4 mm were processed (31st to 38th substrates counting in order from the seed crystal side, relative height positions 0.2 to 0.9 in range) and evaluated for quality. The results of evaluation are shown in Table 3. As will be understood from Table 3, in this Example 3 as well, an SiC single crystal ingot with low dislocation densities and a small Raman index (elastic strain) was obtained.

TABLE 3

| | | | TSD | Sum of BPD |
|---|---|---|---|---|
| Substrate no. | | BPD density | density | density and |
| (relative height) | Raman index | (/cm²) | (/cm²) | TSD density |
| 31 (0.2) | 0.08 | 300 | 160 | 460 |
| 32 (0.3) | 0.07 | 210 | 120 | 330 |
| 33 (0.4) | 0.07 | 110 | 90 | 200 |
| 34 (0.5) | 0.05 | 60 | 90 | 150 |
| 35 (0.6) | 0.04 | 40 | 90 | 130 |
| 36 (0.7) | 0.03 | 40 | 80 | 120 |
| 37 (0.8) | 0.07 | 20 | 80 | 100 |
| 38 (0.9) | 0.01 | 20 | 80 | 100 |

### Example 4: Invention Example of Ingot for Diameter 6 Inch or More Substrate

Next, growth of a single crystal of Example 4 will be explained as an example of the invention of a diameter 6 inch or more substrate-use ingot. The technical idea of crystal growth of Example 4 is similar to Example 1. To control the heat input from side surfaces of the ingot during crystal growth and suppress a change in temperature distribution of the ingot during crystal growth as much as possible (that is, to obtain the above “action of 1)”), the previously shown first means and second means were employed. Further, to grow the crystal by making the temperature gradient in the crystal growth direction relatively small while maintaining the degree of supersaturation of the growth surface (that is, to obtain the “action of 2)”), the crystal was grown by making the temperature gradient Δt₂ in the crystal growth direction smaller than the past methods while lowering the control pressure of the growth space and promoting the diffusion of the sublimation gas to increase the amount of sublimation materials reaching the growth surface (that is, using the above method ii)). In Example 4, a single crystal ingot for obtaining a diameter 150 mm substrate (diameter 6 inch substrate) was obtained.

First, commercially available graphite felt (one set heat treated in advance at 2000° C.) was prepared. This graphite felt was heat treated in a high purity argon atmosphere at 2550° C. for 48 hours and used as an insulating material 6. Further, for the crucible lid 4, as shown in FIG. 2, an integrally formed one where the area around the seed crystal attachment region 4a to which the seed crystal 2 was attached was surrounded by the heat flux control member 15 was used. Here, the seed crystal attachment region 4a is formed from an isotropic graphite material having a diameter of 155 mm (room temperature heat conductivity 125 w/m·K), Further, the heat flux control member 15 was made a donut shape of a diameter of 140 mm of a circular shape concentric with this formed from a pitch-impregnated graphite material (same material as Example 2 with room temperature heat conductivity of 150 w/m·K).

In this Example 4, to prevent deterioration of the insulating material due to leakage of the sublimation gas from the inside of the crucible, members forming the crucible the same as Example 3 were bonded by a commercially available graphite-use adhesive. However, structural parts designed so that gas intentionally can pass were not bonded. By suppressing unintentional gas leakage in this way, a change in temperature gradient due to deterioration of the insulating material was suppressed and the change in temperature field of the crystal was made further smaller.

Further, in this Example 4, as the seed crystal 2, a seed crystal substrate (thickness 1400 μm) of an SiC single crystal comprised of a 4H type single polytype having (0001) face as its main surface, having a <0001> axis slanted 4° in the <11-20> direction, and having a diameter of 154 mm was used. This was attached to the seed crystal attachment region 4a of the above-mentioned crucible lid 4T. The crucible body 3 was filled with about 5800 g of SiC powder as a sublimation material. The area around the crucible 5 was covered by the above heat treated graphite felt to thereby complete the assembly of the single crystal growth apparatus shown in FIG. 1.

Next, a single crystal ingot was produced. Into the high purity Ar gas flowing to the inside of the double quartz tube 7, 25 vol % of helium gas was introduced. Using the conduction of heat of the gas, a temperature gradient smaller than Examples 1 to 3 was aimed at. During growth, the inside of the quartz tube was maintained at a pressure of 0.27 kPa lower than usual growth while changing the partial pressure of the nitrogen gas from 180 Pa to 90 Pa in range maintaining the optimal conductivity in the ingot as a whole at the time of crystal growth. Further, a high frequency current was run through the work coil 9 so that the top temperature of the crucible lid 4 became 2120° C. and the bottom temperature of the crucible body 3 became 2130° C. The temperature difference Δt₂ of the seed crystal temperature and the material temperature at this time was 105° C. This is a condition for the temperature difference being smaller than usual growth. This state was held for 200 hours to produce an SiC single crystal ingot according to Example 4.

In the above obtained SiC single crystal ingot, the crystal growth end at the front end of the ingot had a convex shape, the diameter D was 159.1 mm, and the height H′ of the edge point E was 79.4 mm. Further, the height H of the ingot was 80.9 mm, while the difference “h” of height of the center point O and edge point E was 1.5 mm. The surface of this ingot had dimple-shaped carburized surfaces scattered over it. This was due to the fact that the material was substantially used up due to long time growth before the growth process ends. While there were dimples, leaving aside this point, there were no sub-grain boundaries and other macro defects at the surface and the appearance was good.

As explained above, the surface was carburized, so it was learned that the obtained SiC single crystal ingot had a 4H type single polytype when grinding the surface to expose normal crystal and identifying the polytype of the surface by the spectrum of Raman spectroscopy.

Here, the obtained SiC single crystal ingot was processed into substrates in the same way as Example 1, but it was necessary to grind off 8 mm or so of the surface from the crystal growth end of the front end of the ingot until carburization marks at the surface were completely eliminated, so the substrate at the relative height position 0.9 with respect to the height direction of the ingot could not be fabricated. For this reason, seven mirror surface substrates having relative height positions of 0.2 to 0.8, diameters of 150 mm, and thicknesses of 0.4 mm were processed (counting from the seed crystal side, Nos. 41 to 47) and evaluated for quality. The results of evaluation are shown in Table 4. As will be understood from Table 4, in this Example 4 as well, an SiC single crystal ingot with low dislocation densities and small Raman index (elastic strain) in the relative height position of 0.2 to 0.8 in range was obtained.

Note that, in Example 4, it was not possible to process the substrate at the relative height position 0.9, but the ingot was high in absolute height, so the number of substrates yielded was large. It is more advantageous in productivity than an ingot low in height. Further, by suitably adjusting the growth conditions, it is considered possible to increase the grown height to an extent preventing depletion of the material and optimize the production efficiency.

TABLE 4

| | | | TSD | Sum of BPD |
|---|---|---|---|---|
| Substrate no. | | BPD density | density | density and |
| (relative height) | Raman index | (/cm²) | (/cm²) | TSD density |
| 41 (0.2) | 0.06 | 200 | 280 | 480 |
| 42 (0.3) | 0.05 | 150 | 270 | 420 |
| 43 (0.4) | 0.04 | 120 | 160 | 280 |
| 44 (0.5) | 0.04 | 50 | 80 | 130 |
| 45 (0.6) | 0.03 | 40 | 80 | 120 |
| 46 (0.7) | 0.02 | 40 | 90 | 135 |
| 47 (0.8) | 0.01 | 30 | 90 | 120 |

### Comparative Example 1

Next. Comparative Example 1 will be explained. In Comparative Example 1, except for making the pressure inside the quartz tube 1.33 kPa, the same procedure was followed as in Example 1 to produce an SiC single crystal ingot. That is, the temperature difference of the crystal growth direction was made 150° C., a condition for the temperature difference being smaller than usual growth, and the growth pressure was made the same extent as usual growth. Further, the crystal was grown under the same conditions as in Example 1 for the crucible 5 and insulating material 6 besides the seed crystal and sublimation materials used.

The obtained SiC single crystal ingot had a crystal growth end at the front end of the ingot of a convex shape, a diameter D of 103.7 mm, and a height H′ of an edge point E of 16.7 mm. Further, the height H of the ingot was 20.6 mm, while the difference “h” of height of the center point O and edge point E was 3.9 mm. Further, from this SiC single crystal ingot, eight mirror surface substrates having relative height positions in the ingot in the same way as Example 1, diameters of 100 mm, and thicknesses of 0.4 mm were processed (51st to 58th substrates counting in order from the seed crystal side, relative height positions 0.2 to 0.9 in range) and evaluated for quality. The results of evaluation are shown in Table 5.

As will be understood from Table 5, in this Comparative Example 1, the growth pressure was high relative to the temperature difference Δt₂ between the seed crystal temperature and the material temperature, so the growth speed became extremely small and the ingot became one of a height of 50% or so of the case of Example 1. The temperature gradient of the crystal growth direction at the inside of the ingot was low in the same way as Example 1, so the Raman index was a relatively low value in each substrate, substrates with a high BPD density and TSD density were included, and, in particular, at the second half part of growth of Substrate Nos. 55 to 58, the crystal became one with large dislocation densities.

On the other hand, the convex shape of the crystal growth surface was equivalent to that of the past, so stability of the polytype could be secured up to the No. 54 substrate in the middle of growth. However, the temperature difference Δt₂ of the seed crystal temperature and the material temperature was small, so near the position of the No. 55 substrate, it is believed that the degree of supersaturation at the growth surface fell, sublimation or carburization of the growth surface occurred, and dislocations or different polytypes were formed starting from the carburization. The increase in the dislocation densities such as explained previously was believed be an effect of these.

TABLE 5

| | | | TSD | Sum of BPD |
|---|---|---|---|---|
| Substrate no. | | BPD density | density | density and |
| (relative height) | Raman index | (/cm²) | (/cm²) | TSD density |
| 51 (0.2) | 0.12 | 490 | 310 | 800 |
| 52 (0.3) | 0.11 | 470 | 330 | 800 |
| 53 (0.4) | 0.11 | 340 | 250 | 590 |
| 54 (0.5) | 0.10 | 190 | 210 | 400 |
| 55 (0.6) | 0.09 | 1260 | 460 | 1720 |
| 56 (0.7) | 0.09 | 660 | 580 | 1240 |
| 57 (0.8) | 0.08 | 480 | 520 | 1000 |
| 58 (0.9) | 0.08 | 470 | 620 | 1090 |

### Comparative Example 2

Next, Comparative Example 2 will be explained. In Comparative Example 2, except for making the temperature difference Δt₂ of the seed crystal temperature and the material temperature 250° C. and making the pressure inside the quartz tube 1.33 kPa, the same procedure was followed as in Example 1 to produce an SiC single crystal ingot. That is, the temperature difference of the crystal growth direction and the growth pressure were made the same extent as normal growth. Further, the crystal was grown under the same conditions as in Example 1 for the crucible 5 and insulating material 6 besides the seed crystal and sublimation materials used.

The obtained SiC single crystal ingot had a crystal growth end at the front end of the ingot of a convex shape, a diameter D of 107.5 mm, and a height H′ of an edge point E of 33.1 mm. Further, the height H of the ingot was 37.7 mm, while the difference “h” of height of the center point O and an edge point E was 4.6 mm. Further, from this SiC single crystal ingot, eight mirror surface substrates having relative height positions in the ingot in the same way as Example 1, diameters of 100 mm, and thicknesses of 0.4 mm were processed (61st to 68th substrates counting in order from the seed crystal side, relative height positions 0.2 to 0.9 in range) and evaluated for quality. The results of evaluation are shown in Table 6.

As will be understood from Table 6, in this Comparative Example 2, the temperature difference Δt₂ between the seed crystal temperature and the material temperature was relatively large, but the growth pressure was higher compared with Example 1, so an ingot of a height of substantially the same extent as Example 1 was grown. Further, a convex shape of the crystal growth surface was secured and the 4H polytype was stable over the entire growth. However, as explained above, compared with Example 1, the temperature gradient Δt₂ of the crystal growth direction was larger and further the temperature difference in the plane vertical to the growth direction (in-plane temperature gradient) Δt₁ was also larger, so in each substrate, in the results, both the Raman index and the dislocation density were high.

TABLE 6

| | | | TSD | Sum of BPD |
|---|---|---|---|---|
| Substrate no. | | BPD density | density | density and |
| (relative height) | Raman index | (/cm²) | (/cm²) | TSD density |
| 61 (0.2) | 0.27 | 15360 | 330 | 15690 |
| 62 (0.3) | 0.26 | 14540 | 300 | 14840 |
| 63 (0.4) | 0.25 | 8150 | 340 | 8490 |
| 64 (0.5) | 0.25 | 7140 | 320 | 7460 |
| 65 (0.6) | 0.24 | 5470 | 330 | 5800 |
| 66 (0.7) | 0.22 | 3390 | 390 | 3780 |
| 67 (0.8) | 0.21 | 2300 | 330 | 2630 |
| 68 (0.9) | 0.18 | 2250 | 300 | 2550 |

### Comparative Example 3

Next, Comparative Example 3 will be explained. In Comparative Example 3, due to shrinkage of the temperature gradient (Δt₁) at the growth surface, the size of the heat removal hole 17 provided at the insulating material 6 arranged at the crucible lid 4 was reduced. Along with the change of the conditions, the temperature gradient (Δt2) in the crystal growth direction also became smaller and became about 230° C. Otherwise, the same procedure was performed as in Comparative Example 2 to grow the crystal.

The obtained SiC single crystal ingot had a diameter D of 108.9 mm and a height H′ of the edge point E of 34.9 mm, but the height H of the ingot was 29.8 mm (that is, difference “h” of height of the center point O and an edge point E was −5.1 mm), and the edge part became polycrystallized resulting in a shape gradually rising in a concave shape. For this reason, in the same way as Example 1, it was only possible to fabricate up to the 4th substrate from the seed crystal side if referring to the relative height position in the ingot (No. 71 to No. 74 substrates counting in order from the seed crystal side, relative height positions 0.2 to 0.5 in range). The results of evaluation of quality are shown in Table 7.

In this Comparative Example 3, as explained above, it is not possible to secure a convex shape of the growth surface, from the No. 72 substrate on, different polytypes were mixed, and from the middle of growth on, the edge part of the ingot was polycrystallized. That is, in the results, the in-plane temperature gradient was small, so in the crystal in the range where a substrate could be cut out, a relatively small Raman index was shown, but due to mixture of different polytypes, the dislocation densities in subsequent substrates was extremely high.

TABLE 7

| | | | TSD | Sum of BPD |
|---|---|---|---|---|
| Substrate no. | | BPD density | density | density and |
| (relative height) | Raman index | (/cm²) | (/cm²) | TSD density |
| 71 (0.2) | 0.14 | 490 | 320 | 810 |
| 72 (0.3) | 0.12 | 9750 | 610 | 10360 |
| 73 (0.4) | 0.10 | 16520 | 660 | 17180 |
| 74 (0.5) | 0.10 | 14440 | 550 | 14990 |

### REFERENCE SIGNS LIST

1. sublimation materials
2. seed crystal
3. crucible body
4. crucible lid
4a. seed crystal attachment region
5. crystal growth use crucible
6, insulating material
7. double quartz tube
8. graphite support pedestal
9. work coil
10. piping
11. mass flow controller
12. vacuum exhaust device
13. pressure control device
14. radiation thermometer
15. heat flux control member
16. SiC single crystal ingot
17. heat removal hole

1. An SiC single crystal ingot comprising a silicon carbide (SiC) single crystal formed on a seed crystal,
a crystal growth end of a front end of the ingot having a convex shape,
wherein, when a bottom surface of the ingot at the seed crystal side is zero and a height of the crystal growth end at a position inside from a side surface of the ingot by 10% of the diameter of the ingot is 1, an SiC single crystal substrate cut out from a part of a relative height in a height direction of the ingot of at least 0.2 to 0.8 in range has a basal plane dislocation density of 1000/cm² or less and a threading screw dislocation density of 500/cm² or less at the surface of the substrate, and a Raman index of a difference (A/B) of a Raman Shift value (A) measured at a center part of the substrate and a Raman Shift value (B) measured at an edge part is 0.20 or less.

2. The SiC single crystal ingot according to claim 1,
wherein, when a bottom surface of the ingot at the seed crystal side is zero and a height of the crystal growth end at a position inside from a side surface of the ingot by 10% of the diameter of the ingot is 1, an SiC single crystal substrate cut out from a part of a relative height in a height direction of the ingot of at least 0.2 to 0.9 in range has a basal plane dislocation density of 1000/cm² or less at the surface of the substrate and a threading screw dislocation density of 500/cm² or less, and a Raman index of the difference (A/B) of the Raman Shift value (A) measured at the center part of the substrate and the Raman Shift value (B) measured at the edge part is 0.20 or less.

3. The SiC single crystal ingot according to claim 1,
wherein, when a bottom surface of the ingot at the seed crystal side is zero and a height of the crystal growth end at a position inside from a side surface of the ingot by 10% of the diameter of the ingot is 1, an SiC single crystal substrate from a part of a relative height in a height direction of the ingot of at least 0.2 to 0.8 in range has a basal plane dislocation density of 500/cm² or less at the surface of the substrate and a threading screw dislocation density of 300/cm² or less, and a Raman index of the difference (A/B) of the Raman Shift value (A) measured at the center part of the substrate and the Raman Shift value (B) measured at the edge part is 0.15 or less.

4. The SiC single crystal ingot according to claim 1,
wherein, when a bottom surface of the ingot at the seed crystal side is zero and a height of the crystal growth end at a position inside from a side surface of the ingot by 10% of the diameter of the ingot is 1, an SiC single crystal substrate from a part of a relative height in a height direction of the ingot of at least 0.2 to 0.9 in range has a basal plane dislocation density of 500/cm² or less and a threading screw dislocation density of 300/cm² or less at the surface of the substrate, and a Raman index of the difference (A/B) of the Raman Shift value (A) measured at the center part of the substrate and the Raman Shift value (B) measured at an edge part is 0.15 or less.

5. The SiC single crystal ingot according to claim 1, which has a size giving a diameter 4 inch to less than 6 inch SiC single crystal substrate.

6. The SiC single crystal ingot according to claim 1, which has a size giving a diameter 6 inch or more SiC single crystal substrate.

7. The SiC single crystal ingot according to claim 1, wherein a total of a basal plane dislocation density and threading screw dislocation density observed at the surface of the substrate is 1000/cm² or less.

8. The SiC single crystal ingot according to claim 1, which has substantially a single polytype.

9. The SiC single crystal ingot according to claim 1, wherein a difference in height (O-E) between a center point O of a crystal growth end corresponding to a position of the ingot height and an edge point E on the crystal growth end corresponding to a position inside from a side surface of the ingot by 10% of the diameter is 1 mm to 7 mm.

10. The SiC single crystal ingot according to claim 1 wherein an ingot height is 25 mm or more.
